(19) United States
(12) Patent Application Publication
(10) Pub. No.: US 2006/0189091 A1
(43) Pub. Date: Aug. 24, 2006

(54) Method and system for laser hard marking

(76) Inventor: Bo Gu, North Andover, MA (US)

Correspondence Address: BROOKS KUSHMAN P.C., 1000 TOWN CENTER, TWENTY-SECOND FLOOR, SOUTHFIELD, MI, 48075, US

(21) Appl. No.: 11/270,108

(22) Filed: Nov. 9, 2005

Related U.S. Application Data
(60) Provisional application No. 60/627,781, filed on Nov. 11, 2004.

(51) Int. Cl. B23K 26/16; H01L 21/76

(52) U.S. Cl. 438/401; 219/121.69

(57) ABSTRACT

A method and system for laser hard marking is provided. The laser-marking system produces a hard mark on a semiconductor wafer. The system includes a pulsed laser subsystem that produces a pulsed laser output for marking at a location on the wafer. The pulsed laser subsystem is controlled so that output pulse width remains substantially constant with a variation in at least one of pulse repetition rate and output energy over a range. A beam delivery system delivers the pulsed laser output to the location on the wafer.

### CROSS-REFERENCE TO RELATED APPLICATION

This application claims the benefit of U.S. provisional application Ser. No. 60/627,781, filed Nov. 11, 2004. This application is related to U.S. application Ser. No. 10/438,501, filed May 15, 2003, which is hereby incorporated by reference herein.

### BACKGROUND OF THE INVENTION

1. Field of the Invention

This invention relates to methods and systems for laser hard marking, especially for semiconductor wafers and devices.

2. Background Art

Lasers have been used for laser marking semiconductor wafers for decades. A listing of representative patents and publications generally related to laser marking is now provided. U.S. Pat. No. 5,329,090 relates to dot marking of wafers.

The following representative patent references relate to various aspects of laser marking of wafers and electronic assemblies, illumination, and inspection/reading marks: U.S. Pat. Nos. 4,522,656; 4,945,204; 6,309,943; 6,262,388; 5,929,997; 5,690,846; 5,894,530; 5,737,122; and Japanese Patent Abstract 11135390.

The following representative references provide general information on various laser marking methods and system configurations and components: “Galvanometric and Resonant Low Inertia Scanners”, Montagu, in Laser Beam Scanning, Marcel-Dekker, 1985, pp. 214-216; “Marking Applications now Encompass Many Materials”, Hayes, in Laser Focus World, February 1997, pp. 153-160; “Commercial Fiber Lasers Take on Industrial Markets”, Laser Focus World, May 1997, pp. 143-150. Patent Publications: WO 96/16767, WO 98/53949, U.S. Pat. Nos. 5,965,042; 5,942,137; 5,932,119; 5,719,372; 5,635,976; 5,600,478; 5,521,628; 5,357,077; 4,985,780; 4,945,204; 4,922,077; 4,758,848; 4,734,558; 4,856,053; 4,323,755; 4,220,842; 4,156,124.

Published Patent Applications WO 0154854, publication date Aug. 2, 2001, entitled “Laser Scanning Method and System for Marking Articles such as Printed Circuit Boards, Integrated Circuits, and the Like” and WO 0161275, published on Aug. 23, 2001, entitled “Method and System for Automatically Generating Reference Height Data for use in a Three-Dimensional Inspection System” are both assigned to the assignee of the present invention. Both applications are hereby incorporated by reference in their entirety.

The visibility of laser marks as seen by a vision system (or by operator visual inspection) may depend on several factors including mark depth, debris, etc. which in turn depend on laser material-interaction. For certain wafer marking applications the conventional wisdom leads to relatively large marking depths which may provide for good readability, but increasing susceptibility to subsurface damage.

Wafer marking systems have long been provided by the assignee of the present invention. WaferMark.™ system, produced by the assignee of the present invention for several years, is believed to be the first industrial laser marking system on silicon wafer. Specifications include a 120 μm marking dot diameter hard marking for 300 nm wafers. This meets the SEMI standard specification M1.15. A “soft marking specification” exists for wafer back side soft marking, including marking rough surface back side wafers up to 200 mm wafer. On the “Sigma Clean” system, a backside-marking option is provided for both front and backside marking for up to 200 mm wafer.

There are roughly two kinds of laser marks currently used by the industry, namely soft marks and hard marks. Various marking systems for producing both “hard marks” and “soft marks” have been produced by the assignee of the present invention.

Currently, laser marking systems used for generating hard marks on wafers are provided with lasers having the following characteristic: the laser pulse width (t) varies with the laser pulse energy (E) and repetition rate (f), as shown in FIG. 2. This relationship is typical of conventional q-switched and other pulsed lasers.

Experiments by the applicant showed that marking silicon wafers with such a conventional laser system produced the following marking process characteristics:
The marking depth (z) depends on the number of pulses (#), but not on pulse energy (E) and little on beam expansion (n) (see FIG. 3); and
The marking dot diameter (D) depends on #, E, and n (see FIG. 4).

The mutually conflicting parameters limit marking performance and introduce a tradeoff between the achievable depth, diameter, and quality of the marks. Small diameter, relatively deep, high quality marks represent a challenge and emerging requirement.

As such, it is difficult to get both the mark depth, z, and mark diameter, D, within the customer specifications simultaneously. This is because: one can only vary primarily the number of pulses, #, to obtain the required mark depth, z. If the mark quality is not acceptable at certain number of pulses, then it is very difficult, if not impossible, to get the depth associated with these numbers of pulses. If one tries to change the pulse number, #, to get better quality, the mark diameter, D, will change at the same time. Therefore, lasers utilized in current hard mark laser marking systems give little or no flexibility to improve the mark quality for certain depth and diameter combinations.

### SUMMARY OF THE INVENTION

An object of the present invention is to provide an improved method and system for laser hard marking, especially for semiconductor wafers and devices.

In carrying out the above object and other objects of the present invention, a laser-marking method of marking a semiconductor wafer to form a hard mark having a diameter on the wafer is provided. The method includes controlling a pulsed laser output so that an output pulse width remains substantially constant with a variation in at least one of an output repetition rate and output energy. Depth of the hard mark is affected by a variation in output energy while the diameter of the hard mark, which depends on beam size, remains substantially unchanged as the mark depth changes.

Further in carrying out the above object and other objects of the present invention, a laser-marking method of marking a semiconductor wafer to form a hard mark on the wafer is provided The method includes controlling a pulsed laser output so that a temporal characteristic of at least a portion of the pulsed laser output that affects depth of the hard mark to be formed with the laser output remains substantially constant with a variation in at least one of an output repetition rate and output energy. The depth of the hard mark is affected by a variation in output energy while the diameter of the hard mark, which depends on beam size, remains substantially unchanged as the mark depth changes.

The temporal characteristic and the output energy may be set prior to marking a batch of wafers, and remain set during marking of the entire batch.

The temporal characteristic and the output energy may be set subsequent to positioning a wafer at a marking station, and prior to marking a single wafer.

The temporal characteristic and the output energy may be set subsequent to positioning a wafer at a marking station, and prior to marking a single wafer. The method may further include varying the temporal characteristic and the output energy to produce marks having different predetermined depths on the wafer.

The temporal characteristic and the output energy may be set at a manufacturing site of a laser-marking system, or set at a site where the laser-marking system is installed.

Still further in carrying out the above object and other objects of the present invention, a laser-marking system for producing a hard mark on a semiconductor wafer is provided. The system includes a pulsed laser subsystem that produces a pulsed laser output for marking at a location on the wafer. The pulsed laser subsystem is controlled so that output pulse width remains substantially constant with a variation in at least one of pulse repetition rate and output energy over a range. The system further includes a beam delivery system for delivering the pulsed laser output to the location on the wafer.

A hard mark may be formed with the pulsed laser output and may have a diameter that is substantially independent of depth of the hard mark.

The system may further include a beam expander and a controller having a control program and may be operatively connected to the beam expander for producing a predetermined mark diameter.

The system may further include an attenuator and a controller having a control program and may be operatively connected to the attenuator for controlling energy of a pulse of the pulsed laser output.

Pulse width may be set within a range of about 10 nanoseconds to about 100 nanoseconds.

A typical hard mark may have a depth in a range of 10 microns to 150 microns.

The range may be 20 microns to 120 microns.

The system may further include a controller including a subsystem of electronic components and a control program that may be generally used for marking system control.

The system may further include a controller including at subsystem of electronic components and a control program that may be dedicated to control the laser subsystem.

The subsystem may include a laser having a cavity with a saturable absorber disposed therein.

The above object and other objects, features, and advantages of the present invention are readily apparent from the following detailed description of the best mode for carrying out the invention when taken in connection with the accompanying drawings.

### BRIEF DESCRIPTION OF THE DRAWINGS

FIG. 1 schematically illustrates first and second hardmarks produced within a region of a semiconductor wafer using a laser marking system of one embodiment of the present invention (simplified for illustration, not to scale);

FIG. 2 is a graph of pulse width versus pulse energy for a conventional laser;

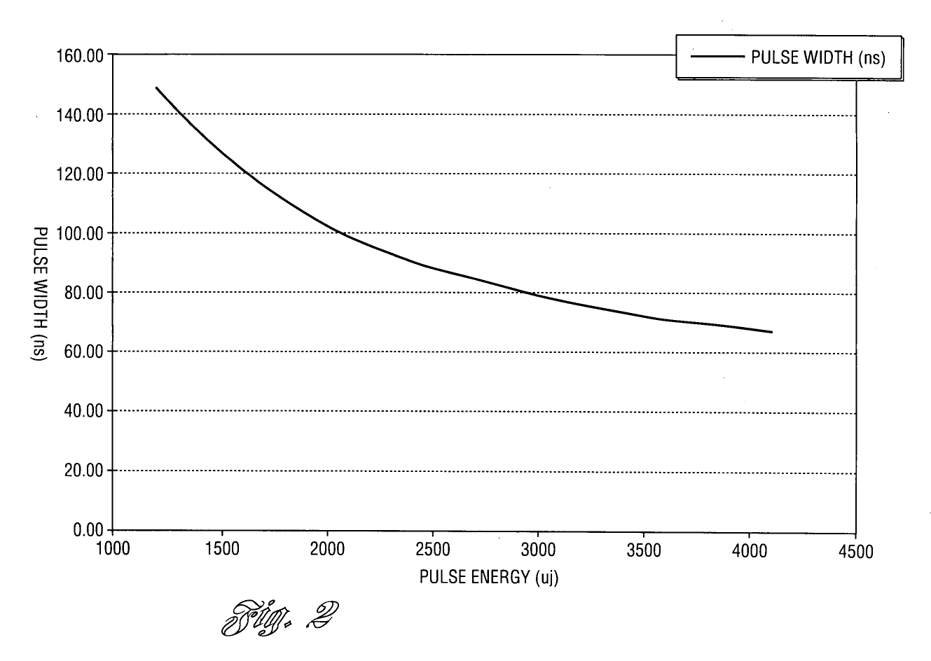

FIG. 3 are graphs of mark depth versus pulse energy for different numbers of pulses and beam expansions for a conventional laser;

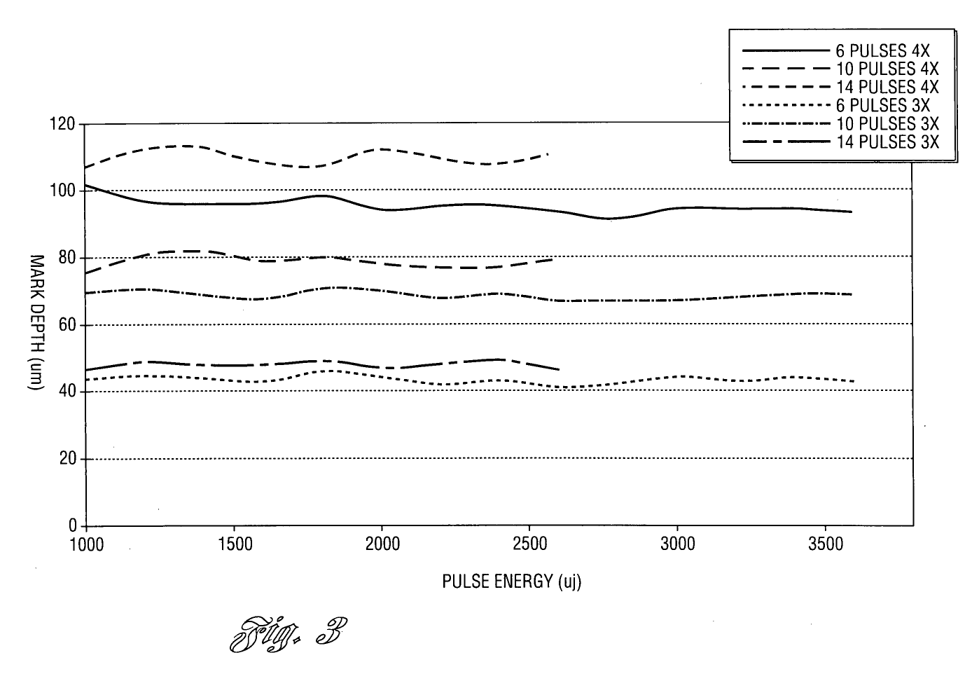

FIG. 4 are graphs of mark diameter versus pulse energy for different numbers of pulses and beam expansions for a conventional laser;

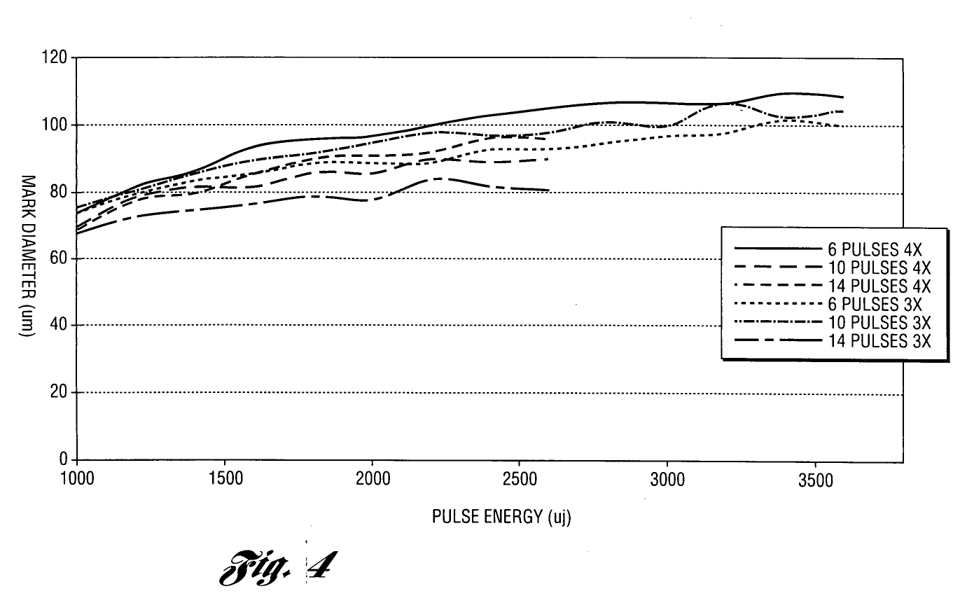

FIG. 5 is a graph of pulse width versus pulse energy of a laser of one embodiment of the invention;

FIG. 6 are graphs of mark diameter versus pulse energy for different numbers of pulses of a laser of one embodiment of the invention; and

FIG. 7 are graphs of mark depth versus pulse energy for different numbers of pulses of a laser of one embodiment of the invention.

### DETAILED DESCRIPTION OF THE PREFERRED EMBODIMENTS

Embodiments of the present invention are typically used for “dot” formats on a first side of a bare wafer, though not so limited. The wafer may be polished to a roughness standard.

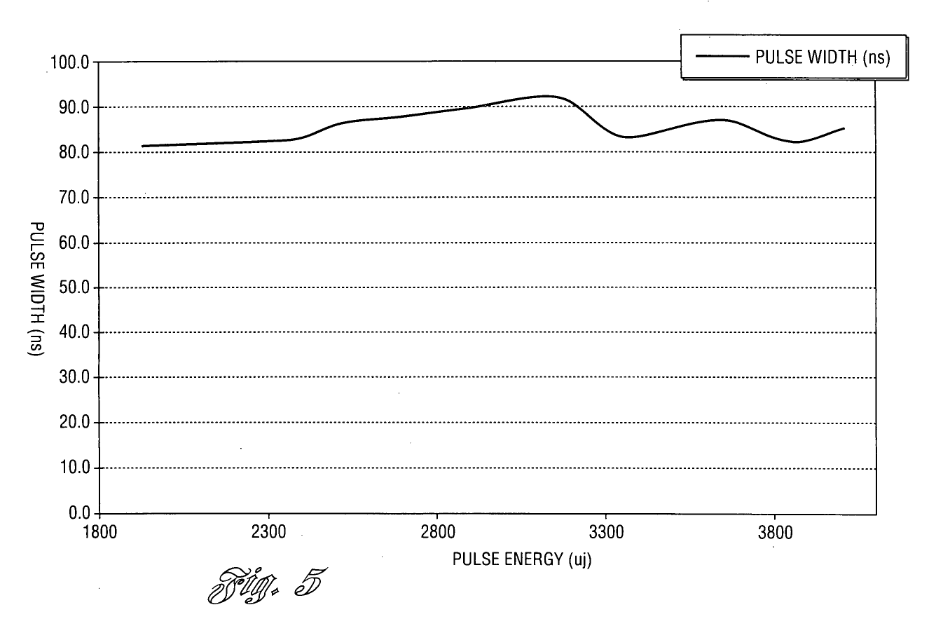

Lasers utilized in embodiments of the present invention will generally include or be configured so that the pulse width, t, is independent of E and f over the processing range, as shown in FIG. 5.

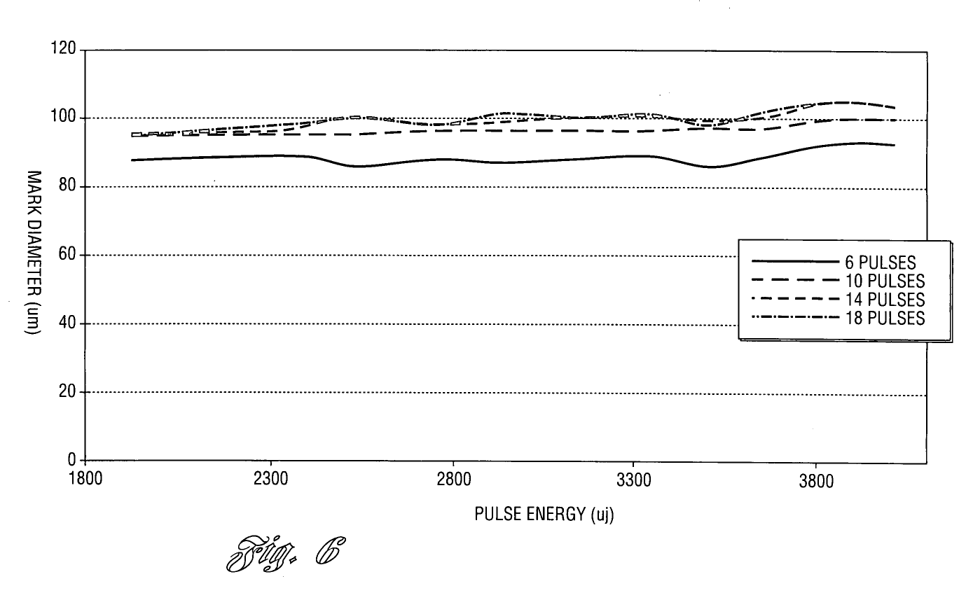

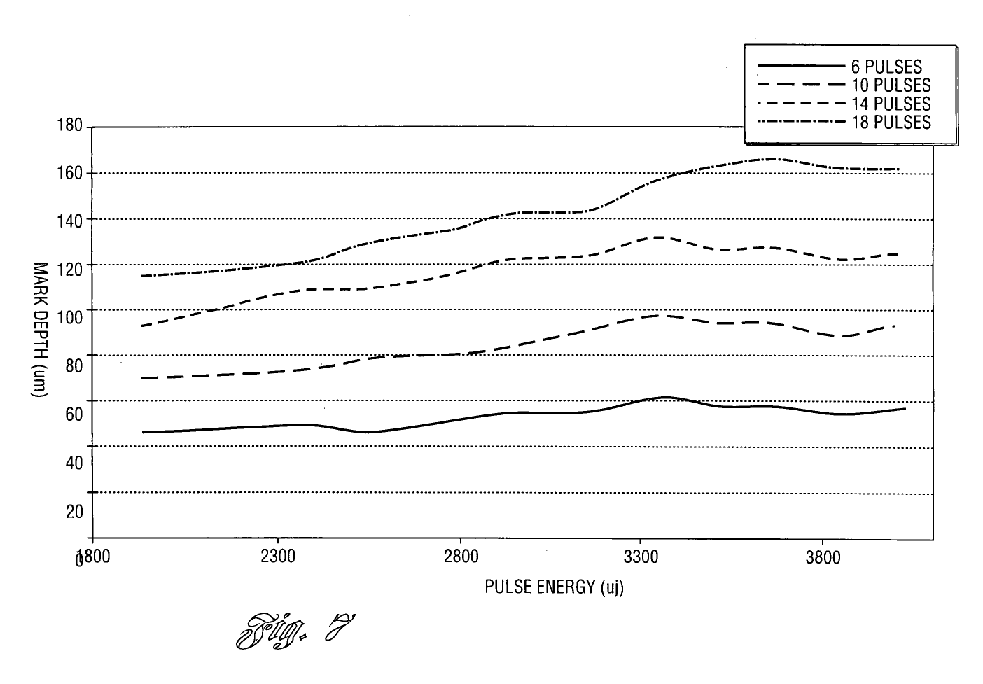

With the pulse width independent of E and f it was discovered that:
The marking diameter (D) does not depend on pulse energy, E, but on optical expansion, n, and slightly on the number of pulses, #, (see FIG. 6); and
The marking depth (z) depends on the number of pulses, #, and pulse energy, E, (z will saturate after certain E) (see FIG. 7).

Now, with an embodiment of the present invention, one can easily achieve any required combination of mark depths and diameters. First, obtain the required mark diameter, D, by selecting the proper beam expansion, n, and the number of laser pulses, #, (for the best marking quality), and then vary the laser pulse energy, E, to get the required mark depth (z) since the diameter, D, will not change with E.

Preferably the marking will occur at the position of best focus at each marking location over a marking field. However, the marking may also occur at positions other than best focus and may occur with off-normal incident marking beams. Typical marks may be about 20-120 microns deep.

There are several ways to achieve the laser characteristic shown in FIG. 5.

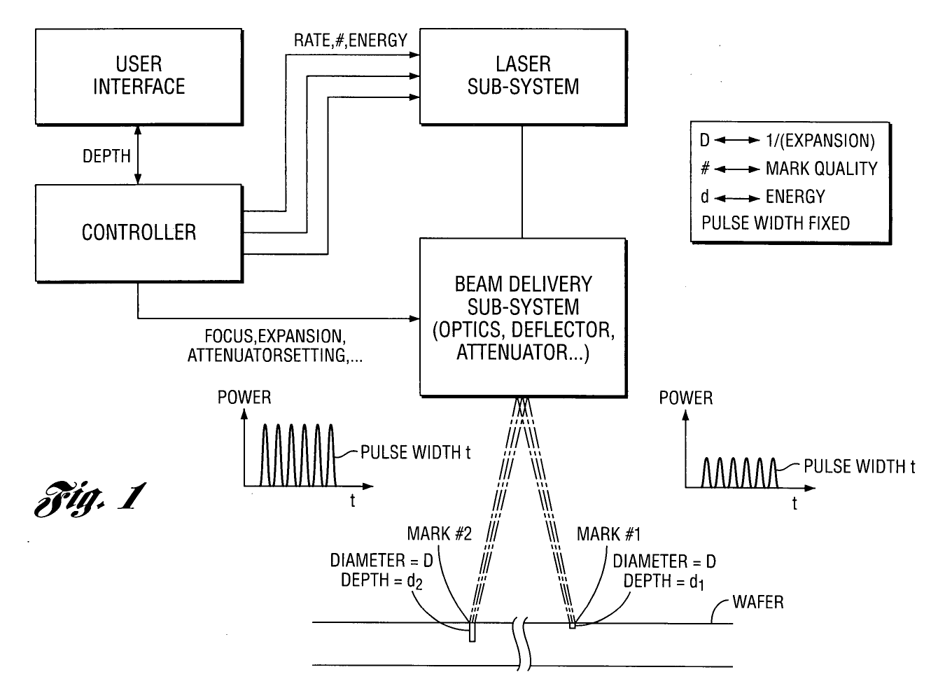

In one exemplary embodiment of a system of the present invention (i.e., FIG. 1), one can put a saturated element in the laser cavity having an absorption coefficient that can be saturated with laser radiation, such an element is known as a “saturable absorber”. Normally the absorption coefficient decreases with increasing of the resonant radiation. An absorber with similar output performance over an applicable range of laser gain and corresponding pump energy (and therefore the output energy range) will provide for a substantially constant pulse width in a q-switched system. The effective output pulse width is a function the peak and average power of the q-switched pulses. A constant pulse width can be set if the q-switch is designed such that the average pulse power and peak power is adjusted according to the corresponding pump laser power or laser gain.

In another embodiment the cavity geometry and cavity optics may be precisely adjusted to obtain constant pulse duration over the preselected energy range.

Various U.S. patents teach control of laser pulse characteristics. By way of example, the teachings of U.S. Pat. Nos. 5,128,609; 5,226,051; 5,812,569, and 6,339,604 each relate to controlling laser pulse characteristics, for instance the energy and/or pulse width. The '569 and '604 patents are assigned to the assignee of the present invention. The teachings of the '609 patent, and specific embodiments disclosed in the '604 patent that relate to micromachining and laser trimming, may be adapted to form hard marks in accordance with the present invention.

In practice, a pulse temporal characteristic, for instance pulse width, may be constant for a lot or batch wafers, without a requirement for further adjustment. Future requirements may lead to setting of the pulse characteristics for hard marking different depths within a field. The surface variations of the wafers lead to a requirement for “process studies” to determine the laser output energy requirement, and such variations generally determine the frequency of such measurements. Preferably, the laser marking system will include detection and calibration hardware and software to perform any needed process studies with minimum operator intervention.

Various embodiments of the present invention may be integrated with the commercially available systems, including the Wafermark® SigmaDSC™ marking products produced by the assignee of the present invention.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A laser-marking method of marking a semiconductor wafer to form a hard mark having a diameter on the wafer, the method comprising:
controlling a pulsed laser output so that an output pulse width remains substantially constant with a variation in at least one of an output repetition rate and output energy, wherein depth of the hard mark is affected by a variation in output energy while the diameter of the hard mark, which depends on beam size, remains substantially unchanged as the mark depth changes.

2. A laser-marking method of marking a semiconductor wafer to form a hard mark on the wafer, the method comprising:
controlling a pulsed laser output so that a temporal characteristic of at least a portion of the pulsed laser output that affects depth of the hard mark to be formed with the laser output remains substantially constant with a variation in at least one of an output repetition rate and output energy, wherein the depth of the hard mark is affected by a variation in output energy while the diameter of the hard mark, which depends on beam size, remains substantially unchanged as the mark depth changes.

3. The method as claimed in claim 2, wherein the temporal characteristic and the output energy are set prior to marking a batch of wafers, and remain set during marking of the entire batch.

4. The method as claimed in claim 2, wherein the temporal characteristic and the output energy are set subsequent to positioning a wafer at a marking station, and prior to marking a single wafer.

5. The method as claimed in claim 2, wherein the temporal characteristic and the output energy are set subsequent to positioning a wafer at a marking station, and prior to marking a single wafer, and wherein the method further comprises varying the temporal characteristic and the output energy to produce marks having different predetermined depths on the wafer.

6. The method as claimed in claim 2, wherein the temporal characteristic and the output energy are set at a manufacturing site of a laser-marking system, or set at a site where the laser-marking system is installed.

7. A laser-marking system for producing a hard mark on a semiconductor wafer, the system comprising:
a pulsed laser subsystem that produces a pulsed laser output for marking at a location on the wafer, the pulsed laser subsystem being controlled so that output pulse width remains substantially constant with a variation in at least one of pulse repetition rate and output energy over a range; and
a beam delivery system for delivering the pulsed laser output to the location on the wafer.

8. The system as claimed in claim 7, wherein a hard mark formed with the pulsed laser output has a diameter that is substantially independent of depth of the hard mark.

9. The system as claimed in claim 7, further comprising a beam expander and a controller having a control program and operatively connected to the beam expander for producing a predetermined mark diameter.

10. The system as claimed in claim 7, further comprising an attenuator and a controller having a control program and operatively connected to the attenuator for controlling energy of a pulse of the pulsed laser output.

11. The system as claimed in claim 7, wherein pulse width is set within a range of about 10 nanoseconds to about 100 nanoseconds.

12. The system as claimed in claim 7, wherein a typical hard mark has a depth in a range of 10 microns to 150 microns.

13. The system as claimed in claim 12, wherein the range is 20 microns to 120 microns.

14. The system as claimed in claim 7 further comprising a controller including a subsystem of electronic components and a control program that is generally used for marking system control.

15. The system as claimed in claim 7 further comprising a controller including at subsystem of electronic components and a control program that is dedicated to control the laser subsystem.

16. The system as claimed in claim 7 wherein the subsystem includes a laser having a cavity with a saturable absorber disposed therein.
